(19) United States
(12) Patent Application Publication
(10) Pub. No.: US 2005/0208769 A1
(43) Pub. Date: Sep. 22, 2005

(54) Semiconductor structure

(76) Inventor: Manish Sharma, Sunnyvale, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/805,471

(22) Filed: Mar. 19, 2004

(51) Int. Cl. H01L 21/20; H01L 21/302

(52) U.S. Cl. 438/700; 216/17; 438/733

(57) ABSTRACT

A semiconductor structure is fabricated by etching semiconductor material to form one or more recesses having side walls. The semiconductor material on the side walls is then reacted to form an oxide of the semiconductor material. This oxide may be then selectively removed from the side walls of the recess(es). This leads to a semiconductor structure having a high aspect ratio which is defined as the depth of the recess(es) divided by the width of the semiconductor material between the recess(es).

### FIELD OF THE INVENTION

The present invention relates to a semiconductor structure and a method of fabricating a semiconductor structure. In particular, although not exclusively, the invention relates to a semiconductor structure which has semiconductor features having a high aspect ratio defined as the depth of the feature divided by the width of the feature.

### BACKGROUND TO THE INVENTION

Memory devices used for storing data in computer systems typically comprise an array of memory cells. These memory cells are linked by a grid of conductors running in the longitudinal direction and the transverse direction. These memory cells typically have integrated semiconductor elements such as diodes or transistors. For example, magneto-resistive random access memory (MRAM) devices may have a diode integrated into each MRAM cell for the prevention of sneak currents. A dynamic random access memory (DRAM) typically includes an access field-effect transistor (FET) and a storage capacitor. The access FET allows the transfer of data charges to and from the storage capacitor during reading and writing operations.

A semiconductor array is typically formed by processes of masking and etching. In the known process of lithography, a mask is created on the semiconductor substrate, whereupon the unmasked regions can be etched away. The minimum feature size that can be created is therefore determined by the lithographic process. The minimum feature size will therefore determine the array dimensions and therefore the data storage capacity of a memory device.

A known fabrication method for DRAM involves building up layers of doped semiconductor material to form the p type and n type layers of a transistor and then subsequently forming trenches in the layered structured by etching. Pillars of layers of npn material thereby form transistors in a grid array. During the various masking and etching steps, oxidation of the base of the trenches occurs. In order to protect the side walls of the trenches, silicon nitride is deposited by chemical vapour deposition to be subsequently removed. The purpose of the nitride layers on the side walls of the trenches is to protect the adjacent layers of the transistor pillars during the oxidation process.

It would be desirable to form semiconductor structures having high aspect ratios.

### SUMMARY OF THE INVENTION

A method of fabricating a semiconductor structure comprises etching the semiconductor material to form at least one recess having side walls. The side walls of the semiconductor material are then reacted to form an oxide of the semiconductor material. This oxide is selectively removed from the side walls of the at least one recess.

### BRIEF DESCRIPTION OF THE DRAWINGS

FIGS. 1 to 4 illustrate in schematic cross-section, the fabrication of transistors in accordance with one embodiment of the present invention;

FIG. 5 is a schematic perspective view of an array of diodes constructed in accordance with an embodiment of the present invention;

FIG. 6 is a schematic side view of PIN diodes formed in accordance with the present invention.

FIGS. 7 to 15 illustrate in schematic cross-section, the fabrication of a transistor in accordance with another embodiment of the present invention.

### DESCRIPTION OF PREFERRED EMBODIMENTS

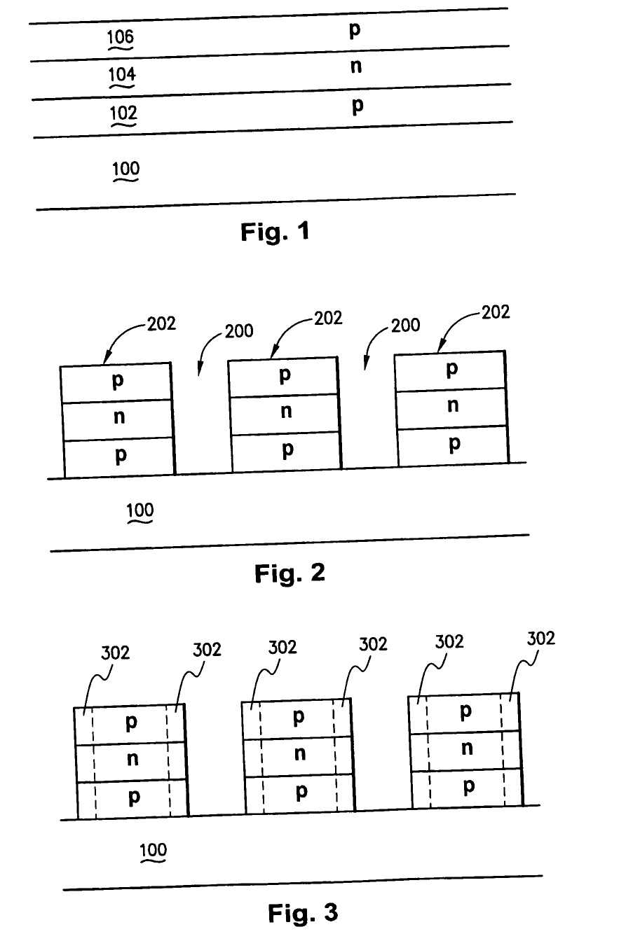

FIG. 1 illustrates a substrate 100 with layers of p type and n type material 102, 104 and 106 formed on the substrate 100. The substrate 100 may comprise a silicon crystal wafer with the layers of p type and n type material built up by conventional epitaxial methods. Alternatively, the layers of p type and n type material may be constructed of amorphous or polycrystalline silicon. The process may involve the low temperature deposition of the appropriately doped p type and n type of silicon, either in amorphous or polycrystalline phase. In a preferred form of the invention, plasma-enhanced chemical vapour deposition (PECVD) is employed. Other techniques include pulsed laser deposition (PLD) which involves irradiating the amorphous or polycrystalline silicon following the introduction of dopants. This results in the crystallisation of the silicon and simultaneously in the activation of the dopants via ultra fast melting and solidification.

Such low temperature deposition can be carried out with relatively little heating of the underlying substrate 100. Accordingly, the silicon layers can therefore be deposited on low temperature substrates such as ceramics, dielectrics, glass or polymers. Furthermore, as the process preserves the substrate, the silicon layers can be constructed over underlayers and structures such as silicon integrated circuits. It will therefore be appreciated that through the use of lower temperature deposition of amorphous or polycrystalline silicon, multiple layers of semiconductor devices may be built up one atop the other. If the semiconductor devices in the layers are arranged in arrays then multiple arrays of the semiconductor devices may be built one atop the other. The silicon layers 102, 104 and 106 may be built over a planarized dielectric layer or a quartz layer.

FIG. 2 illustrates the formation of recesses in the form of trenches 200 through the layers 102, 104 and 106 of semiconductor material. If these trenches 200 are arranged in orthogonal grids then the remaining material of the layers 102, 104 and 106 will form pillars 202 of semiconductor material.

The patterning of the deposited silicon material layers may initially form longitudinal and transverse trenches simultaneously. Alternatively, it is possible that parallel lines of longitudinal trenches may be initially formed, followed by the subsequent formation of parallel lines of transversely extending trenches. The latter case is particularly desirable where the etched depth for the longitudinal trenches is required to be different than the etched depth for the transverse trenches. Alternatively, the patterning may simply create parallel lines of trenches creating one or more ridges of semiconductor material.

The formation of the trenches may initially involve a lithographic process followed by deep silicon anisotropic etching techniques. This has been achieved at dimensions in the range of 50 nm to 150 nm for the width of the remaining material between the trenches. Widths down to 10 nm may also be achieved.

The outside of the silicon pillars 202 is then subject to thermal oxidation to form native oxide regions 302. The side walls of the pillars 202 may be selectively oxidized by initially providing a protective nitride layer on the tops of the pillars 202 and the bases of the trenches 200. Alternatively, the tops of the pillars and the bases of the trenches may be oxidised also. The oxide on the tops of the pillars can be removed in a later planarizing step.

Typically, thermal oxidation involves using a standard semi-conductor processing furnace at a temperature of approximately 900 to 1100°. In this environment, the silicon pillars 202 may be exposed to an oxygen or steam atmosphere.

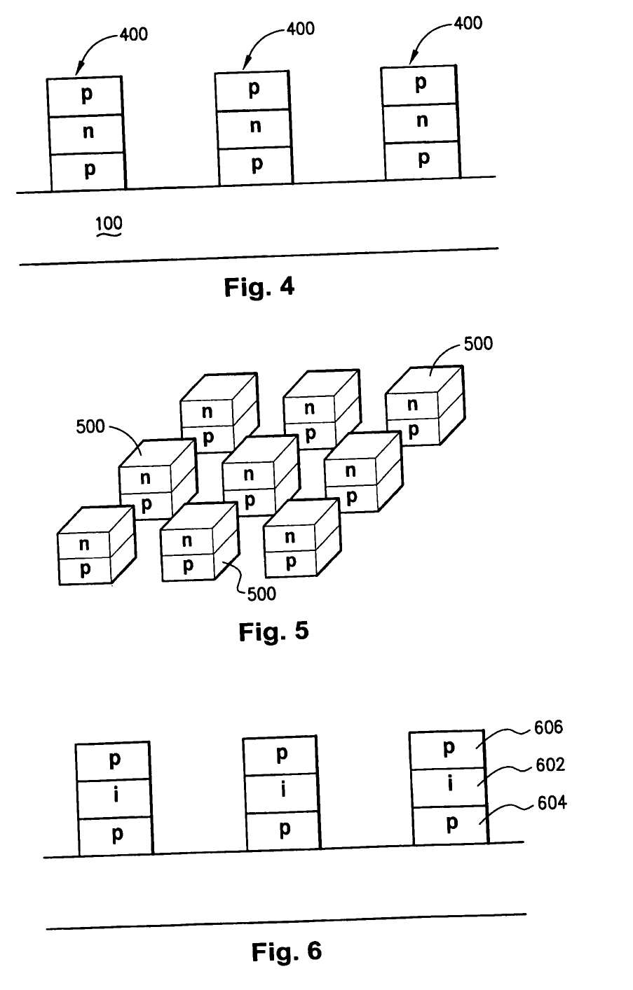

As shown in FIG. 4, the oxidized regions 302 are then removed from the side walls of the pillars 202 to form even thinner pillars. This enables pillar widths in the range of 10-100 nm wide with pillar heights in the range of 200-400 nm. This provides high aspect ratios for the resulting transistor pillars 202. Typically, the aspect ratios are greater than 10:1. Preferably, the aspect ratios are in the range of 10:1 to 50:1. Another preferred range is 10:1 to 20:1.

The foregoing describes the construction of a pnp type transistor 400 as shown in FIG. 4. Appropriate connections may be made to the regions of the connector in subsequently processing steps. For example, it is possible that the transistors 400 may be constructed over the top of a conductor line formed within substrate 100. Furthermore, gate connections may be formed within the trenches between the transistors 400. Additional space between the trenches may be filled with isolation materials such as dielectric material. Further, conductor lines may be formed above the transistors 400. For example, the conductor lines may be formed by a copper damascene process. The conductor lines may be arranged orthogonal to each other so as to form a cross-linked array of transistors.

Furthermore, the transistors 400 may form part of other devices including memory devices, including MRAM, DRAM or any other type of cross-linked memory array.

FIGS. 1 to 4 illustrate the construction of a pnp type transistor. A similar process may be used to form a npn type transistor. Furthermore, diode pillars may also be constructed as per the array of diode pillars 500 illustrated in FIG. 5. Likewise, FIG. 6 illustrates a formation of a positive-intrinsic-negative diode. This is a photodiode with a large neutrally doped intrinsic region (i) 602 sandwiched between p doped and n doped semiconductor regions 604, 606 on substrate 600. Nevertheless, the principles of construction remain similar to those explained in conjunction with FIGS. 1 to 4.

While the forgoing description in FIGS. 1 to 4 concerns a silicon based technology (regular; any orientation; crystalline; polysi; amorphous, strained Si; SiGe, SiC), it will be appreciated that other semiconductor material may be employed, such as III-V and II-VI semiconductors.

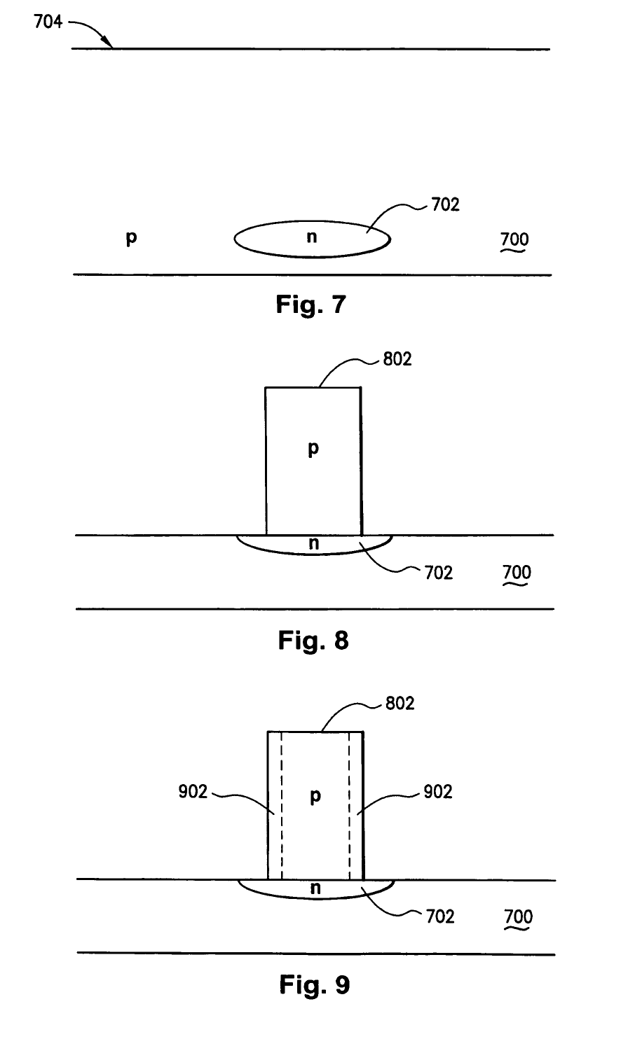

FIGS. 7 to 15 illustrate the fabrication of a field effect transistor according to a second preferred embodiment as shown in FIG. 15. Referring to FIG. 7, a substrate in the form of a silicon wafer 700 is doped with p type impurities. By means of deep ion implantation, n type impurities are introduced into a region 702 spaced from the surface 704 of the substrate 700. As will be explained, the n type region will become the source of the transistor. A region above the n type impurity region 702 will form the channel of the transistor. A further region of n type impurities may also be introduced closer to the surface 704 of the substrate 700 to become the drain of the transistor. However, this is not shown in the preferred embodiment and instead, the drain region is separately deposited as will be explained in conjunction with FIG. 15.

The p type substrate 700 may comprise a single crystal substrate. Alternatively, the p type region 700 may comprise amorphous silicon deposited on an insulator (not shown).

As shown in FIG. 8, the silicon material has been patterned to define a pillar 802. The silicon substrate 700 is etched down to the n type region 702 so that the silicon pillar 802 of p type material is disposed on the n type region 702. The patterning is conducted by lithography in conjunction with deep anisotropic etching.

In FIG. 9, the substrate 700 and pillar 802 are subjected to thermal oxidation. This is shown to produce oxide regions 902 on the sides of the pillar 802. In reality, oxides form on all surfaces including the top of the pillar 802. The oxide material on the top of the pillar 802 can be removed in a later planarizing step.

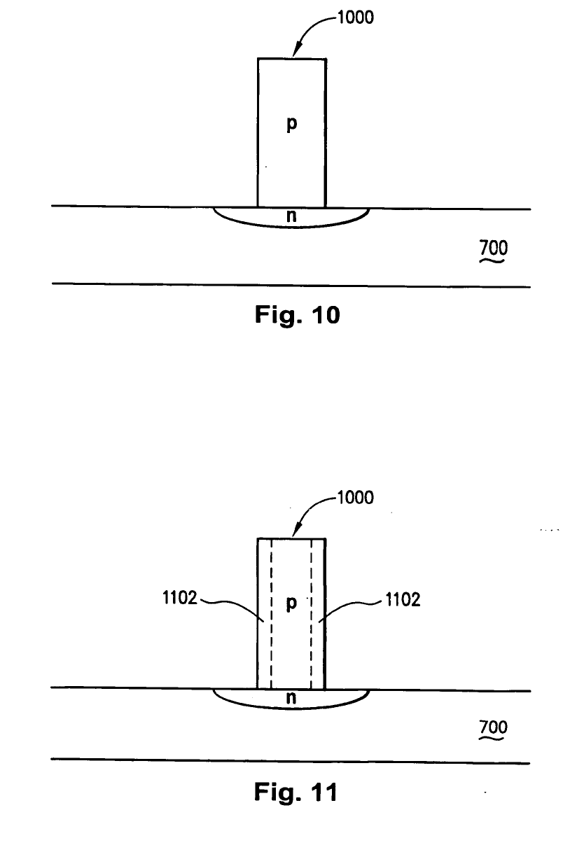

As shown in FIG. 10, the oxide regions 902 are removed by reactive ion etching (RIE). This results in a slimmed down pillar 1000 as shown in FIG. 10, thus leading to a greater aspect ratio for the pillar 1000.

As shown in FIG. 11, the pillar 1000 may be subjected to further thermal oxidization to produce gate oxide regions 1102 on the sides of the pillar 1000. Alternatively, the gate oxide regions 1102 could be formed by leaving some of the oxide regions 902 behind to constitute the gate oxide. However, the steps shown in FIGS. 10 and 11 are preferred.

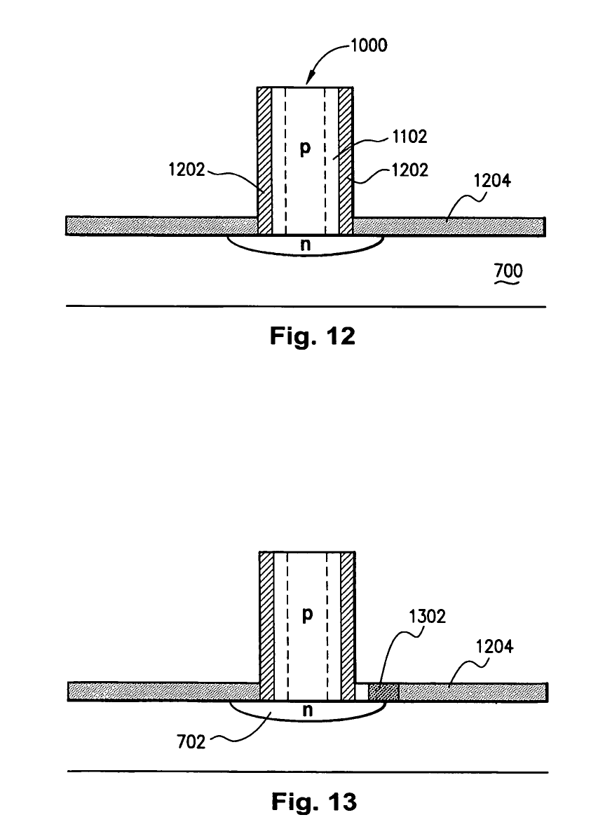

In FIG. 12, platinum is deposited onto the side walls of the pillar 1000 to form gates 1202. Platinum has been shown to work well for this purpose, however other metals which will adhere to the side walls of the pillar 1000 could be substituted. Additionally, a gate line could be patterned from platinum deposited in either or both recesses adjacent to the pillar 1000 in an alternative form of the invention.

As shown in FIG. 12, a dielectric material 1204 is deposited on the substrate region 700. While this is shown as a separate material, the dielectric region 1204 could simply constitute silicon dioxide formed as a result of the thermal oxidation described in conjunction with FIGS. 9 and 11.

As per FIG. 13, a via is etched into the dielectric region 1204. Metal is deposited to form a silicide contact such as Tungsten silicide or cobolt silicide. This via contact 1302 makes contact with the n type region 702 as shown.

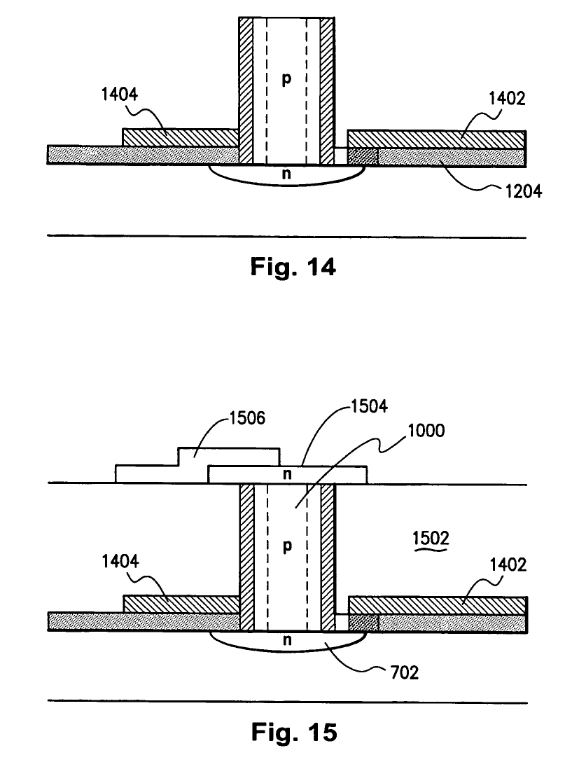

Referring to FIG. 14, conductor lines including a source line 1402 and a gate line 1404 are then formed above the dielectric material 1204. These may be formed of any suitable metal such as platinum or copper. Copper line conductors may be made by a copper damascene process.

Referring to FIG. 15, the space above the conductors is then covered by a second dielectric material 1502. This material is then planarized to the top of pillar 1000 and in so doing, the top oxide layers of the pillar 1000 are removed. n type material may be deposited on top of the pillar 1000 to form the drain 1504 for the transistor. This n type material may be deposited as a layer which is then etched back to a region within the top of the pillar 1000. Given the deposition of the further n type material, it will be appreciated that the second dielectric region 1502 should constitute silicon dioxide. A drain line 1506 may then be formed in contact with the drain 1504 as appropriate. Further dielectric material (not shown) may be added to the top and planarized level where desired.

It will be understood that the p type region of the pillar 1000 forms the channel of a vertical MOSFET transistor. The length of the channel is equal to the height of the pillar 1000 which is determined by the extent of the selective vertical etching which takes place in FIG. 8. Thus, the separate formation of the source 702 and drain 1504 means that the channel length can be made the full length of the extent which can be achieved by the anisotropic etching. Thus, long channel lengths can be created which extend vertically and thus do not take up valuable silicon real estate. There are certain operational benefits which can be achieved by a long channel length. For example, with a long narrow channel, a smaller bias will be required to reach the pinch-off voltage. Furthermore, with a long channel, a variation in composition can be made along the channel to give rise high frequency effects as will be understood by those skilled in the art. Such high frequency effects may include carrier mobility modulations and concentration variations along the channel. One could also use bandgap-engineered materials and also superlattices since the channel length is set only by the height of the pillar.

While the foregoing enhancement type describes the particular arrangement of an n channel MOSFET, it will be understood that the invention could also be adapted to a depletion type MOSFET or even a p channel MOSFET. Further, with substitution of the metal oxide gates for a pn junction, a JFET transistor could also be made. Furthermore, the arrangement is not limited to having the drain and the source in the positions as shown and may be reversed.

It will be understood that the use of a vertical transistor or diode structure will be particularly beneficial where diodes or transistors are intended to be incorporated into a MRAM array. This will help to achieve much smaller MRAM cell sizes. However, the invention is not to be seen as limited to transistors, diodes and other semiconductor features in an array structure.

While the embodiment above is described in terms of diodes and transistors having high aspect ratios, the invention is not to be seen as limited to these types of semiconductor features and may indeed cover other types of semiconductor features. Furthermore, the invention is not limited to arrays of semiconductor features and may embody single semiconductor features or combinations of different types of semiconductor features.

In accordance with a second aspect of the present invention, there is provided a semiconductor structure which comprises semiconductor material having recesses formed therein. The aspect ratio is defined as the depth of the one or more recesses divided by the width of the semiconductor material between the recesses. This aspect ratio is greater than 10:1.

In accordance with a third aspect of the invention there is provided a method of forming a transistor having a source, drain and channel, the method comprising: forming in semiconductor material, a first region of a first conductivity type spaced from the surface of the semiconductor material and a second region of a second conductivity type between the surface of the material and the first region; forming at least one recess in the semiconductor material to form a pillar between the sides of the at least one recess; wherein the first region is disposed below the pillar and defines one of the source and the drain of the transistor and the second region defines the channel of the transistor.

1. A method of fabricating a semiconductor structure comprising:
etching semiconductor material to form at least one recess having side walls;
reacting the semiconductor material on the side walls to form an oxide of the semiconductor material; and
selectively removing the oxide from the side walls of the at least one recess.

2. The method as claimed in claim 1 wherein the semiconductor material is silicon.

3. The method as claimed in claim 1 wherein the reaction takes place by thermal oxidation of silicon.

4. The method as claimed in claim 2 wherein the removal of the oxide of silicon is conducted by selective etching.

5. The method as claimed in claim 1 wherein the at least one recess is formed by deep anisotropic etching.

6. The method as claimed in claim 1 wherein the at least one recess comprises a plurality of trenches.

7. The method as claimed in claim 6 wherein the trenches are arranged in a grid pattern to define an array of pillar structures.

8. The method as claimed in claim 1 wherein the at least one recess is arranged to define at least one pillar structure comprising layers of appropriately doped semiconductor material to form a diode.

9. The method as claimed in claim 7 wherein the at least one recess is arranged to define at least one pillar structure comprising layers of appropriately doped semiconductor material to form a transistor.

10. The method as claimed in claim 1 wherein the at least one recess comprises a plurality of recesses and the aspect ratio, defined as the depth of the recesses divided by the width of the semiconductor material between adjacent recesses is greater than 10:1.

11. A semiconductor structure when formed by the method of claim 1.

12. A semiconductor structure comprising semiconductor material having a plurality of recesses formed therein, wherein the aspect ratio, defined as the depth of the recesses divided by the width of the semiconductor material between adjacent recesses is greater than 10:1.

13. The semiconductor structure as claimed in claim 12 wherein the semiconductor material is silicon.

14. The semiconductor structure as claimed in claim 12 wherein the recesses comprise a plurality of trenches.

15. The semiconductor structure of claim 14 wherein the trenches define ridges therebetween.

16. The semiconductor structure as claimed in claim 14 wherein the trenches are arranged in a grid pattern to define an array of pillar structures.

17. The semiconductor structure as claimed in claim 12 wherein the recesses define at least one pillar structure comprising layers of appropriately doped semiconductor material to form at least one diode.

18. The semiconductor structure as claimed in claim 12 wherein the recesses define at least one pillar structure comprising layers of appropriately doped semiconductor material to form at least one transistor.

19. A method of forming a transistor having a source, drain and channel, the method comprising: forming in semiconductor material, a first region of a first conductivity type spaced from the surface of the semiconductor material and a second region of a second conductivity type between the surface of the material and the first region; forming at least one recess in the semiconductor material to form a pillar between the sides of the at least one recess; wherein the first region is disposed below the pillar and defines one of the source and the drain of the transistor and the second region defines the channel of the transistor.

20. The method as claimed in claim 19 wherein a third region is formed above the second region and defines the other of the source and the drain of the transistor.

21. The method as claimed in claim 20 wherein the pillar is formed by a process of etching and the third region is deposited subsequent to the step of etching.

22. The method as claimed in claim 21 wherein the pillar is formed by the process of deep anisotropic etching.

23. The method as claimed in claim 19 wherein the first region is formed by deep ion implantation.
